(19) United States
(12) Patent Application Publication
(10) Pub. No.: US 2024/0103216 A1
(43) Pub. Date: Mar. 28, 2024

(54) VERTICAL THROUGH-SILICON WAVEGUIDE FABRICATION METHOD AND TOPOLOGIES

(71) Applicant: Intel Corporation, Santa Clara, CA (US)

(72) Inventors: Sagar SUTHRAM, Portland, OR (US); John HECK, Berkeley, CA (US); Ling LIAO, Fremont, CA (US); Mengyuan HUANG, Cupertino, CA (US); Wilfred GOMES, Portland, OR (US); Pushkar RANADE, San Jose, CA (US); Abhishek Anil SHARMA, Portland, OR (US)

(21) Appl. No.: 17/954,292

(22) Filed: Sep. 27, 2022

(51) Int. Cl. G02B 6/12; H01L 25/16

(52) U.S. Cl. CPC G02B 6/12004; H01L 25/167

(57) ABSTRACT

Embodiments disclosed herein include through silicon waveguides and methods of forming such waveguides. In an embodiment, a through silicon waveguide comprises a substrate, where the substrate comprises silicon. In an embodiment, a waveguide is provided through the substrate. In an embodiment, the waveguide comprises a waveguide structure. and a cladding around the waveguide structure.

### TECHNICAL FIELD

Embodiments of the disclosure are in the field of semiconductor structures and processing and, in particular, to through silicon waveguides for optical signaling.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

Variability in conventional and currently known fabrication processes may limit the possibility to further extend them into the 10 nanometer node or sub-10 nanometer node range. Consequently, fabrication of the functional components needed for future technology nodes may require the introduction of new methodologies or the integration of new technologies in current fabrication processes or in place of current fabrication processes.

In the manufacture of integrated circuit devices, multi-gate transistors, such as tri-gate transistors and gate-all-around (GAA) transistors, have become more prevalent as device dimensions continue to scale down. Tri-gate transistors and GAA transistors are generally fabricated on either bulk silicon substrates or silicon-on-insulator substrates. In some instances, bulk silicon substrates are preferred due to their lower cost and compatibility with the existing high-yielding bulk silicon substrate infrastructure.

Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

### BRIEF DESCRIPTION OF THE DRAWINGS

FIG. 1A is a plan view illustration of a waveguide structure in a cavity in a silicon substrate, in accordance with an embodiment.

FIG. 1B is a cross-sectional illustration of the waveguide structure in FIG. 1A, in accordance with an embodiment.

FIG. 1C is a plan view illustration of the waveguide structure after it is lined with a cladding, in accordance with an embodiment.

FIG. 1D is a cross-sectional illustration of the waveguide structure in FIG. 1C, in accordance with an embodiment.

FIG. 1E is a plan view illustration of the waveguide structure after a fill layer is deposited in order to fill the cavity around the waveguide structure, in accordance with an embodiment.

FIG. 1F is a cross-sectional illustration of the waveguide structure in FIG. 1E, in accordance with an embodiment.

FIG. 2A is a plan view illustration of a waveguide structure that is cross shaped, in accordance with an embodiment.

FIG. 2B is a plan view illustration of a waveguide structure that is T-shaped, in accordance with an embodiment.

FIG. 3A is a plan view illustration of a waveguide structure with a silicon nitride lining, in accordance with an embodiment.

FIG. 3B is a cross-sectional illustration of the waveguide structure in FIG. 3A, in accordance with an embodiment.

FIG. 3C is a plan view illustration of the waveguide structure after a fill layer fills the cavity around the waveguide structure, in accordance with an embodiment.

FIG. 3D is a cross-sectional illustration of the waveguide structure in FIG. 3C, in accordance with an embodiment.

FIG. 3E is a plan view illustration of the waveguide structure after the sacrificial post is removed, in accordance with an embodiment.

FIG. 3F is a cross-sectional illustration of the waveguide structure in FIG. 3E, in accordance with an embodiment.

FIG. 3G is a plan view illustration of the waveguide structure after a fill layer replaces the sacrificial post, in accordance with an embodiment.

FIG. 3H is a cross-sectional illustration of the waveguide structure in FIG. 3G, in accordance with an embodiment.

FIG. 4A is a plan view illustration of a waveguide structure with through silicon vias (TSVs), in accordance with an embodiment.

FIG. 4B is a cross-sectional illustration of the waveguide structure in FIG. 4A, in accordance with an embodiment.

FIG. 4C is a cross-sectional illustration of the waveguide structure after a carrier is attached, in accordance with an embodiment.

FIG. 4D is a cross-sectional illustration of the waveguide structure after the substrate is thinned to expose the waveguide, in accordance with an embodiment.

FIG. 4E is a cross-sectional illustration of the waveguide structure after a plurality of waveguide structures are stacked, in accordance with an embodiment.

FIG. 4F is a cross-sectional illustration of the waveguide structure after the carrier is removed, in accordance with an embodiment.

FIGS. 5A-5E are cross-sectional illustrations depicting a process for attaching photonic integrated circuits (PICs) to the waveguide structure, in accordance with an embodiment.

FIG. 6A is a cross-sectional illustration of a pair of dies that are optically coupled together by a waveguide structure, in accordance with an embodiment.

FIG. 6B is a cross-sectional illustration of a pair of interposers that are optically coupled together by a waveguide structure, in accordance with an embodiment.

FIG. 7A is a cross-sectional illustration of a glass waveguide structure, in accordance with an embodiment.

FIG. 7B is a cross-sectional illustration of a glass waveguide structure with lenses, in accordance with an embodiment.

FIG. 7C is a cross-sectional illustration of a pair of dies optically coupled together by a glass waveguide structure, in accordance with an embodiment.

FIG. 7D is a cross-sectional illustration of a pair of dies optically coupled together by a glass waveguide structure with lenses, in accordance with an embodiment.

FIG. 8A is a cross-sectional illustration of an optical fiber optically coupled to a die through a vertical waveguide structure, in accordance with an embodiment.

FIG. 8B is a cross-sectional illustration of an optical fiber optically coupled to a die through a vertical glass waveguide structure, in accordance with an embodiment.

FIG. 9 illustrates a computing device in accordance with one implementation of an embodiment of the disclosure.

FIG. 10 illustrates an interposer that includes one or more embodiments of the disclosure.

### DESCRIPTION OF THE EMBODIMENTS

Embodiments described herein comprise through silicon waveguides for optical signaling and methods of forming such waveguides. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As data rates between components in an electronic system continue to increase, there is a growing need for new interconnect architectures other than electrical interconnects. One solution is to use optical waveguides in order to send optical signals between components of the electronic system. In an optical solution, a photonics integrated circuit (PIC) is provided at each end of the optical waveguide. The PICs then interface with electrical integrated circuits (EICs) on the dies or interposer that are communicating with each other. However, vertically oriented optical waveguides have not been developed in order to enable vertical stacking of components.

Accordingly, embodiments disclosed herein include through silicon waveguides (TSWs). The silicon provides a robust structure that is capable of supporting a first interposer (or die) over a second interposer. The TSWs also enable high data rates between the interposers. While described as TSWs, it is to be appreciated that vertically oriented waveguides may also be formed from other materials. As will be described herein, vertically oriented waveguides may also include glass substrates and the like.

In an embodiment, the TSWs may be assembled using a plurality of TSW layers. Each layer may have a thickness between approximately 10 μm and approximately 50 μm. When layered over each other, the combined height of the TSWs may be approximately 100 μm or greater. As used herein, “approximately” may refer to a range of values within ten percent of the stated value. For example, approximately 100 μm may refer to a range from 90 μm to 110 μm.

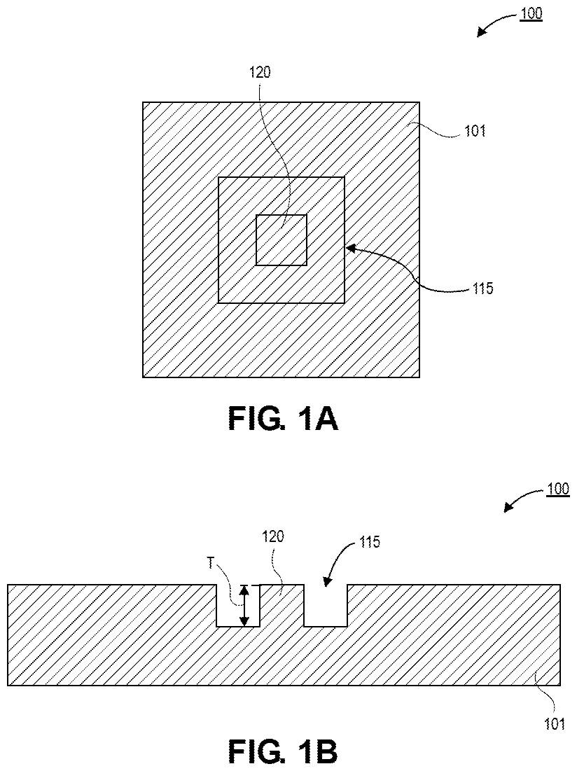

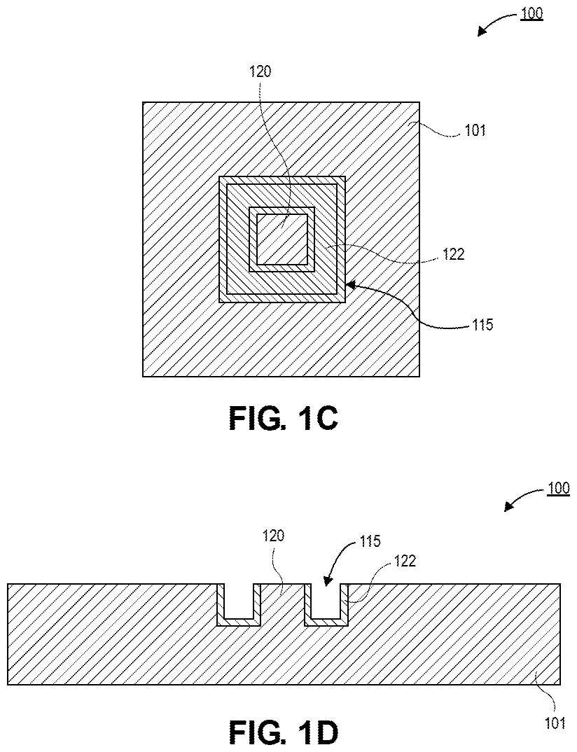

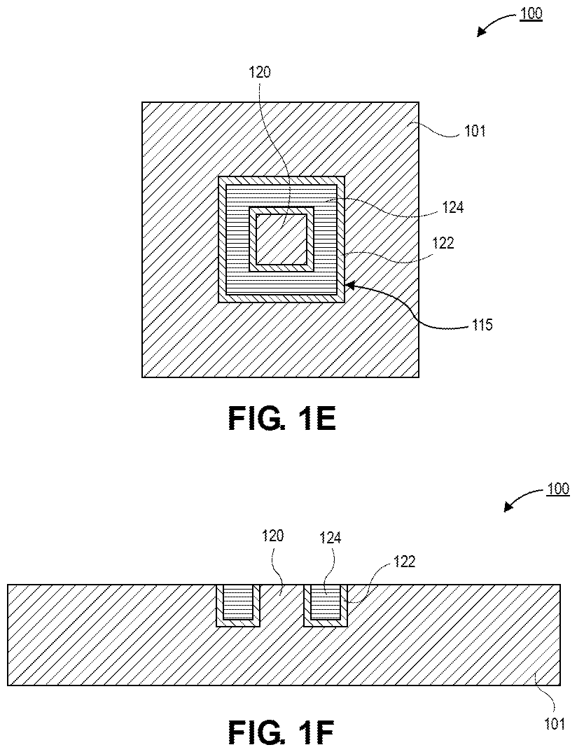

Referring now to FIGS. 1A-1F, a series of illustrations depicting a process of forming a layer of a TSW 100 is shown, in accordance with an embodiment. In the embodiment shown in FIGS. 1A-1F, the TSW comprises a silicon substrate and a waveguide that passes through the silicon substrate. The waveguide may comprise a waveguide structure (which is also silicon in FIGS. 1A-1F) and a cladding around the waveguide structure.

Referring now to FIG. 1A and FIG. 1B, a plan view illustration and a cross-sectional illustration of a TSW 100 at a stage of manufacture is shown, in accordance with an embodiment. In an embodiment, the TSW 100 may comprise a substrate 101. The substrate 101 may be a semiconductor substrate, such as a substrate comprising silicon. In an embodiment, the substrate 101 may have a thickness that is approximately 50 μm or greater. Generally, the substrate 101 may have a full wafer thickness of approximately 700 μm or more, or up to approximately 800 μm. More particularly, the substrate 101 has a thickness that is greater than a thickness T of a waveguide structure 120 that is formed into the substrate 101. For example, the thickness T of the waveguide structure 120 may be approximately 10 μm to approximately 50 μm. The waveguide structure 120 may be provided in a cavity 115. In the illustrated embodiment, the cavity 115 has vertical sidewalls. Though in some instances the sidewalls may be sloped. The waveguide structure 120 and the cavity 115 may be formed with an etching process. Since the waveguide structure 120 is formed from the substrate 101, the waveguide structure 120 may comprise the same material as the substrate 101 (e.g., silicon).

In the particular embodiment shown in FIG. 1A, the waveguide structure 120 has a substantially rectangular (e.g., square) shape. Though, as will be described in greater detail below, the waveguide structure 120 does not need to have a rectangular shape. In an embodiment, the waveguide structure 120 may be considered a high aspect ratio feature. For example, the aspect ratio (height:width) may be approximately 10:1 or greater or 50:1 or greater. For example, a width of the waveguide structure 120 may be approximately 1 μm or more in some embodiments. Additionally, the cavity 115 may have a width of approximately 1 μm or more on each side of the waveguide structure 120.

Referring now to FIG. 1C and FIG. 1D, illustrations of the TSW 100 after a cladding 122 is applied is shown, in accordance with an embodiment. In an embodiment, the cladding 122 may be applied with any suitable conformal deposition process (e.g., chemical vapor deposition (CVD) or the like). In an embodiment, the cladding 122 may be applied as a blanket deposition process. As such, portions of the cladding 122 may be provided over the top surfaces of the substrate 101 and the waveguide structure 120. The excess cladding 122 may be removed with a polishing process (e.g., chemical mechanical polishing (CMP) or the like). In other embodiments, a mask layer may be used in order to selectively deposit the cladding 122 in the cavity 115. In other embodiments, the cladding 122 may be formed with a thermal process, such as a thermal oxidation process. In an embodiment, the cladding 122 may be any suitable material that enables total internal reflection of light used for signaling along the waveguide structure 120. For example, the cladding 122 may comprise silicon and oxygen (e.g., silicon oxide), silicon and nitrogen (e.g., silicon nitride), or the like. In an embodiment, the cladding 122 may have a U-shaped cross-section. That is, the cladding 122 may extend up sidewalls of the cavity 115 and over a bottom surface of the cavity 115. In some instances, the combination of the waveguide structure 120 and the cladding 122 may be referred to together as being a waveguide that passes through the substrate 101.

Referring now to FIG. 1E and FIG. 1F, illustrations of the TSW 100 after a fill layer 124 is deposited into the cavity 115 is shown, in accordance with an embodiment. In an embodiment, the fill layer 124 may fill the remainder of the cavity 115 not filled by the cladding 122. In some embodiments, the fill layer 124 may be deposited with a CVD process, a physical vapor deposition (PVD) process, or the like. Excess fill layer 124 over the top surfaces of the substrate 101 and the waveguide structure 120 may be removed with a polishing process, such as a CMP process. In an embodiment, the fill layer 124 may be the same material as the cladding 122. In other embodiments, the fill layer 124 may be a different material than the cladding 122.

At this point in the process flow, the fabrication of the TSW 100 is partially completed. As will be described in greater detail below, the portion of the substrate 101 below the waveguide structure 120 may be removed with a polishing process, such as a CMP process. The thinned substrate 101 may then be stacked with other thinned substrates in order to fabricate a TSW with a high aspect ratio.

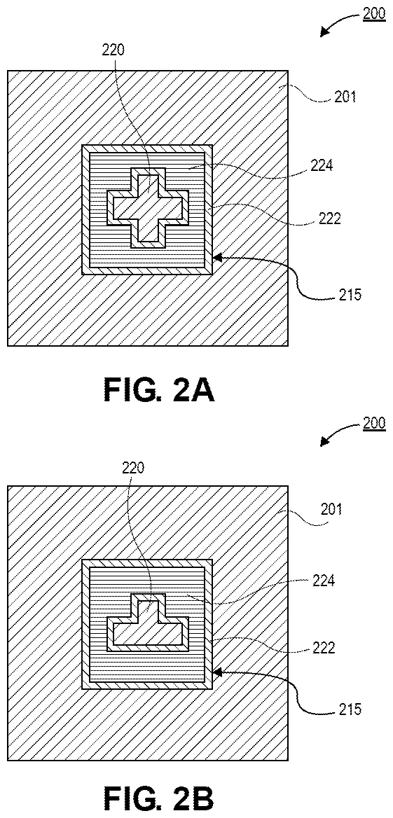

Referring now to FIG. 2A and FIG. 2B, examples of TSWs 200 that include different shaped waveguide structures 220 are shown, in accordance with an embodiment. The different shape of the waveguide structures 220 may enable improved signaling. For example, the different shapes may enable single optical mode signaling. While two different examples are shown in FIGS. 2A and 2B, it is to be appreciated that the waveguide structures 220 may take any shape used in optical signaling solutions.

Referring now to FIG. 2A, a plan view illustration of a TSW 200 is shown, in accordance with an embodiment. In an embodiment, the TSW 200 may comprise a substrate 201. The substrate may comprise silicon or any other suitable semiconductor material. In an embodiment, a waveguide structure 220 is patterned into the substrate 201. For example, the waveguide structure 220 in FIG. 2A may be referred to as being cross-shaped. That is, a first line intersects a second line. The lines may be substantially orthogonal to each other. The cladding 222 may then be formed along the edges of the waveguide structure 220 and along edges of the cavity 215 around the waveguide structure 220. A fill layer 224 may surround the waveguide structure 220.

Referring now to FIG. 2B, a plan view illustration of a TSW 200 is shown, in accordance with an additional embodiment. In an embodiment, the TSW 200 may comprise a substrate, such as a silicon substrate or the like. In an embodiment, a waveguide structure 220 is patterned into the substrate 201. For example, the waveguide structure 220 in FIG. 2B may be referred to as being T-shaped. That is, a first line may be provided at an end of a second line. The first line may be substantially orthogonal to the second line. The cladding 222 may then be formed along the edges of the waveguide structure 220 and along edges of the cavity 215 around the waveguide structure 220. A fill layer 224 may surround the waveguide structure 220.

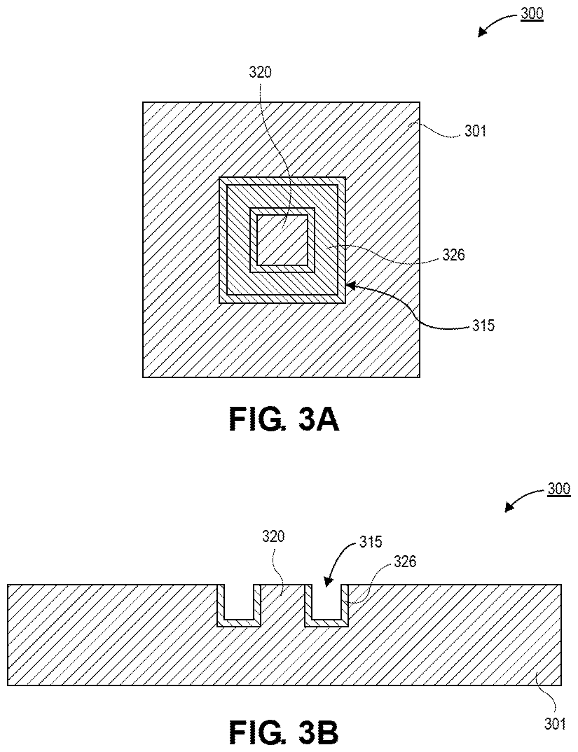

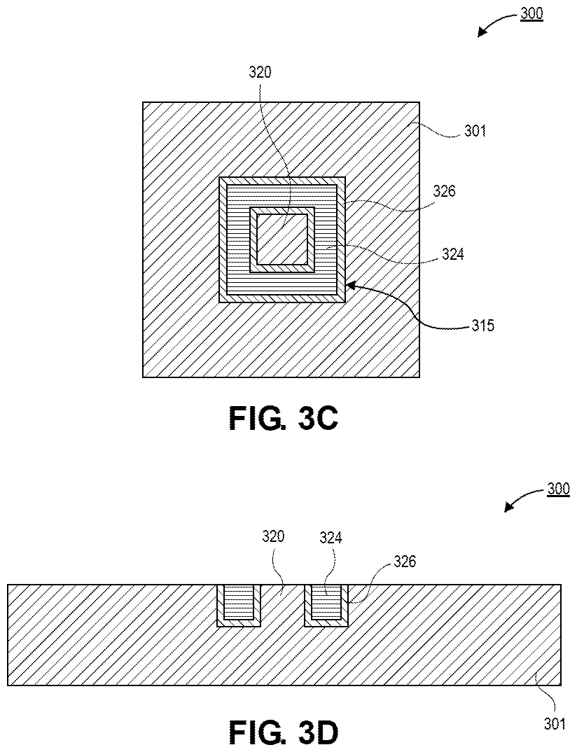

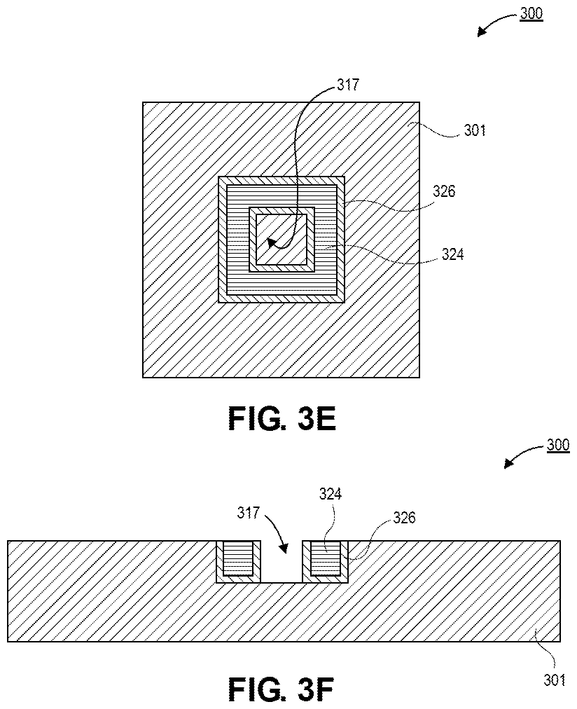

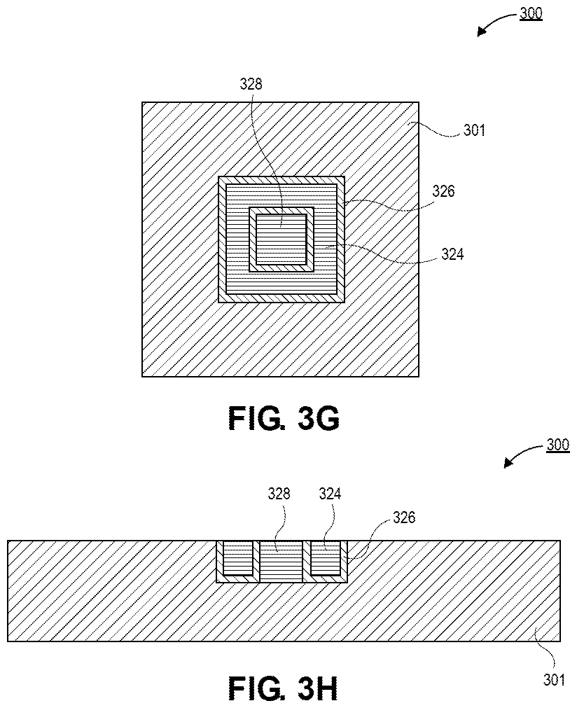

Referring now to FIGS. 3A-3H, illustrations depicting a process for forming a TSW 300 is shown, in accordance with an additional embodiment. In an embodiment, the TSW 300 may comprise a waveguide structure that is a material that is different than that of the substrate 301. In such an embodiment, a sacrificial post is provided in order to form the waveguide structure, the sacrificial post is then removed, and a waveguide structure is filled with a cladding.

Referring now to FIG. 3A and FIG. 3B, a plan view illustration and a cross-sectional illustration of a TSW 300 at a stage of manufacture is shown, in accordance with an embodiment. In an embodiment, the TSW 300 may comprise a substrate 301, such as a silicon substrate or the like. In an embodiment, a cavity 315 is etched into the substrate 301. A sacrificial post 320 may remain in a center of the cavity 315. In an embodiment, the sacrificial post 320 may be substantially similar to the waveguide structure 120 described in greater detail above. In an embodiment, the sidewalls of the cavity 315 and the sidewalls of the sacrificial post 320 may be lined with a waveguide structure 326. The waveguide structure 326 may comprise silicon and nitrogen (e.g., silicon nitride). The waveguide structure 326 may be applied with a CVD process or the like.

Referring now to FIG. 3C and FIG. 3D, a plan view illustration and a cross-sectional illustration of the TSW 300 after the cavity 315 is filled with a fill layer 324 is shown, in accordance with an embodiment. In an embodiment, the fill layer 324 may be a material similar to the waveguide structure 326. In other embodiments, the fill layer 324 may be a different material than the waveguide structure 326. For example, when the waveguide structure 326 comprises silicon and nitrogen, the fill layer 324 may comprise silicon and oxygen. In an embodiment, the fill layer 324 may be deposited with a CVD process, a PVD process, or the like. Excess fill layer 324 over the substrate 301 and the sacrificial post 320 may be removed with a polishing process, such as a CHIP process.

Referring now to FIG. 3E and FIG. 3F, a plan view illustration and a cross-sectional illustration of the TSW 300 after the sacrificial post 320 is removed is shown, in accordance with an embodiment. In an embodiment, the sacrificial post 320 may be removed with an etching process. Removal of the sacrificial post 320 results in the formation of a second cavity 317 within the waveguide structure 326.

Referring now to FIG. 3G and FIG. 3H, a plan view illustration and a cross-sectional illustration of the TSW 300 after a second fill layer 328 is provided in the second cavity 317 is shown, in accordance with an embodiment. In an embodiment, the second fill layer 328 may be the same material as the fill layer 324. In other embodiments, the second fill layer 328 may be a different material than the fill layer 324. The resulting structure comprises a shell type waveguide structure 326 that has inner and outer cladding from the fill layer 324 and the second fill layer 328.

In FIGS. 1A-3H, the illustrations depict processes for forming a first portion of a TSW. It is to be appreciated that multiple TSWs may be attached in a stack in order to provide TSWs with higher aspect ratios in order to span larger distances. For example, multiple TSWs may be stacked in order to form TSWs with heights that are approximately 100 μm or greater.

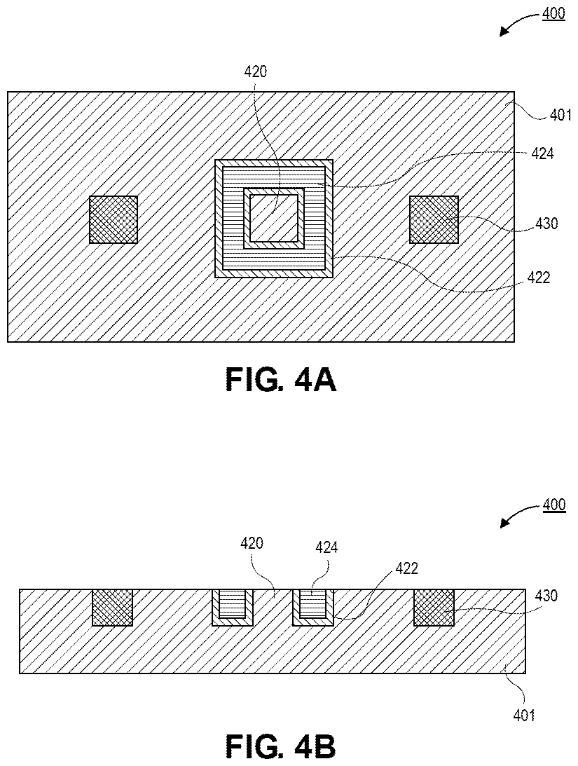

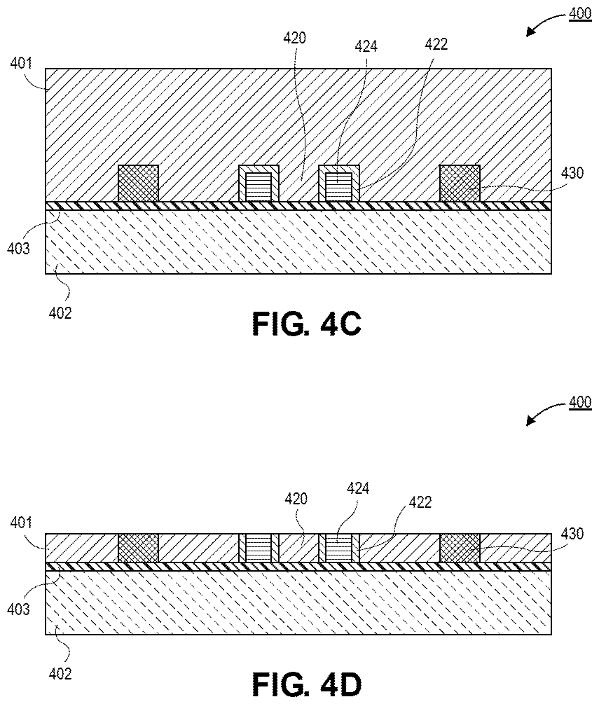

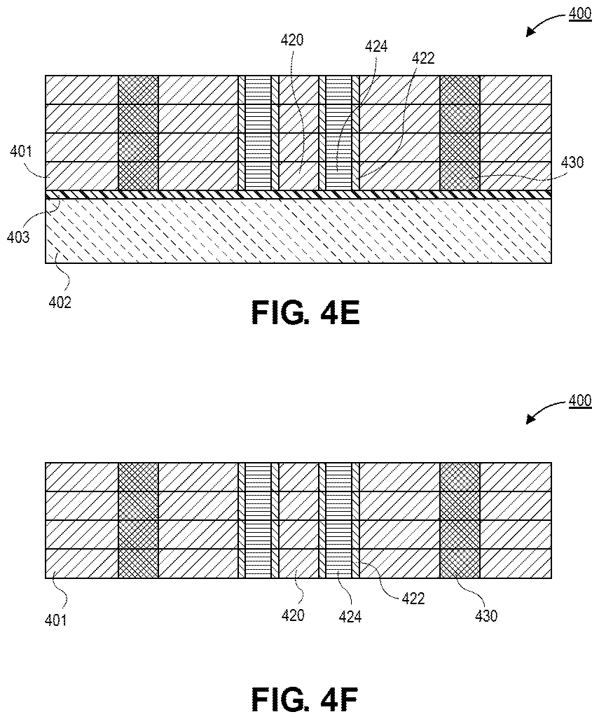

Referring now to FIG. 4A and FIG. 4B, a plan view illustration and a cross-sectional illustration of a TSW 400 at a stage of manufacture is shown, in accordance with an embodiment. As shown, the TSW 400 may comprise a substrate 401, such as a silicon substrate or the like. A waveguide comprising a waveguide structure 420 and a cladding 422 may be provided in the substrate 401. The process for forming the waveguide may be similar to any of the process flows described in greater detail above. Additionally, one or more through silicon vias (TSVs) 430 may be embedded in the substrate 401 adjacent to the waveguide. As shown, the TSVs 430 do not extend entirely through a thickness of the substrate 401. For example, the TSVs 430 may have a height substantially equal to the height of the waveguide structure 420. In subsequent processing operations, the bulk of the substrate 401 is removed in order to expose the bottom side of the TSVs 430 and the waveguide structure 420.

Referring now to FIG. 4C, a cross-sectional illustration of the TSW 400 after the substrate 401 is attached to a carrier 402 is shown, in accordance with an embodiment. In an embodiment, the carrier 402 may be attached to the substrate 401 with an adhesive layer 403. The carrier 402 may be a rigid material. In some instances, the carrier 402 may comprise silicon. Though, glass carriers may also be used in some embodiments. The carrier 402 may be attached to the top surface of the substrate 401 so that the waveguide structure 420 and the TSVs 430 are facing down towards the carrier 402.

Referring now to FIG. 4D, a cross-sectional illustration of the TSW 400 after the substrate 401 is recessed is shown, in accordance with an embodiment. In an embodiment, the substrate 401 may be recessed with a polishing process, such as CMP or the like. The recessing of the substrate 401 is done to a depth to expose the waveguide structure 420 and the backside surfaces of the TSVs 430. At this point, the substrate 401 may have a thickness that is between approximately 10 μm and approximately 50 μm. Though, thicker or thinner substrates 401 may also be provided in FIG. 4D, depending on the height of the waveguide structure 420.

Referring now to FIG. 4E, a cross-sectional illustration of the TSW 400 after a plurality of layers are stacked together is shown, in accordance with an embodiment. In an embodiment, each layer may include a substrate 401, a waveguide structure 420, a cladding 422, a fill layer 424, and TSVs 430. The layers may be bonded together using a hybrid bonding process. A hybrid bond refers to an interface that includes at least two different materials that are bonded together. For example, silicon (e.g., from the substrates 401 and the waveguide structures 420) may be bonded together and metal (e.g., from the TSVs 430) may be bonded together. The bonding of the material may be done with a diffusion bonding process. That is, there may not be a need for solder or other bonding material to be provided between the layers of the TSW 400.

Referring now to FIG. 4F, a cross-sectional illustration of the TSW 400 after the carrier 402 is removed is shown, in accordance with an embodiment. In an embodiment, the carrier 402 may be removed with any suitable process. The adhesion layer 403 may also be cleaned from the surface of the TSW 400. In an embodiment, the resulting TSW 400 may have a height that is approximately 100 μm or greater. In the illustrated embodiment, the TSW 400 includes four layers. However, it is to be appreciated that TSWs 400 may include two or more layers.

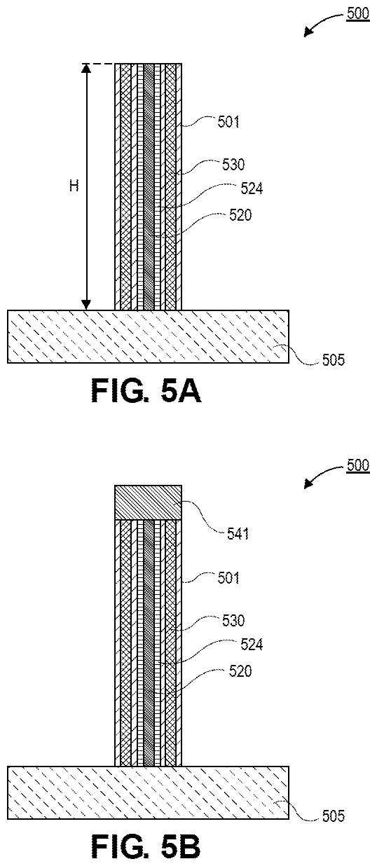

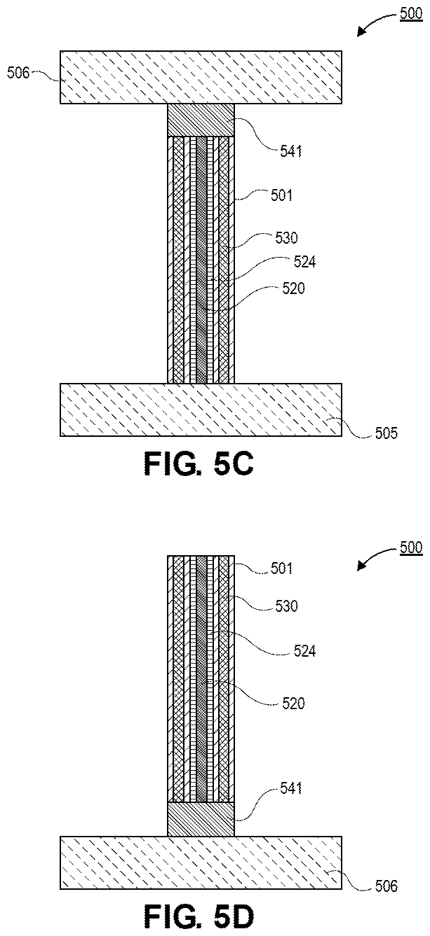

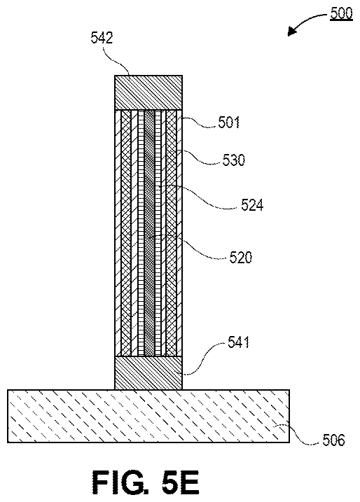

Referring now to FIGS. 5A-5E, a series of cross-sectional illustrations depicting a process for assembling photonics integrated circuits (PICs) 541 and 542 to TSWs 500 is shown, in accordance with an embodiment. In an embodiment, the PICs enable communication with electrical integrated circuits (EICs) that are provided on dies in order to allow for optical communication between dies. In the illustrated embodiments shown in FIGS. 5A-5E, the TSWs 500 are shown as a single monolithic structure. However, it is to be appreciated that the TSWs 500 may be formed with a plurality of layers using any of the processes described in greater detail above.

Referring now to FIG. 5A, a cross-sectional illustration of a TSW 500 at a stage of manufacture is shown, in accordance with an embodiment. In an embodiment, the TSW 500 is supported by a carrier 505, such as a silicon or glass substrate. In an embodiment, the TSW 500 has a height H. The height H may be approximately 100 μm or more. Though, shorter heights H may also be used in some embodiments. In an embodiment, the TSW 500 comprises a substrate 501, TSVs 530, a fill layer 524, and a waveguide structure 520. While not shown in FIG. 5A, it is to be appreciated that a cladding may also be provided between the fill layer 524 and the waveguide structure 520.

Referring now to FIG. 5B, a cross-sectional illustration of the TSW 500 after a first PIC 541 is attached is shown, in accordance with an embodiment. In an embodiment, the PIC 541 may be attached to an end of the TSW 500 opposite from the carrier 505. The PIC 541 may include functionality to convert an optical signal to an electrical signal and to convert electrical signals to optical signals. The PIC 541 may be coupled to the TSW 500 using hybrid bonding or the like.

Referring now to FIG. 5C, a cross-sectional illustration of the TSW 500 after a second carrier 506 is coupled to the PIC 541 is shown, in accordance with an embodiment. In an embodiment, the carrier 506 may be coupled to the PIC 541 with any suitable adhesion layer or the like.

Referring now to FIG. 5D, a cross-sectional illustration of the TSW 500 after the structure is flipped is shown, in accordance with an embodiment. In an embodiment, the second carrier 506 and the first PIC 541 are positioned at the bottom of the TSW 500. In an embodiment, after flipping the TSW 500, the first carrier 505 may be removed. As such, a top surface of the TSW 500 is exposed.

Referring now to FIG. 5E, a cross-sectional illustration of the TSW 500 after a second PIC 542 is attached to the TSW 500 is shown, in accordance with an embodiment. In an embodiment, the second PIC 542 may be attached to the TSW 500 with a hybrid bonding process or the like. In an embodiment, the second PIC 542 may be substantially similar to the first PIC 541. By having PICs 541 and 542 on opposite ends of the TSW 500, optical signals can be propagated along the TSW 500 and the optical signal can be converted to electrical signals at the ends of the TSW 500. After the second PIC 542 is attached, the second carrier 506 may be removed.

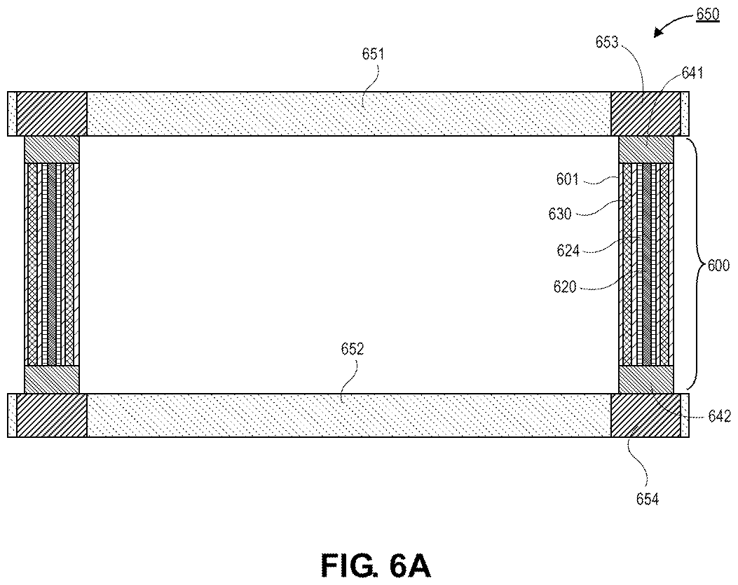

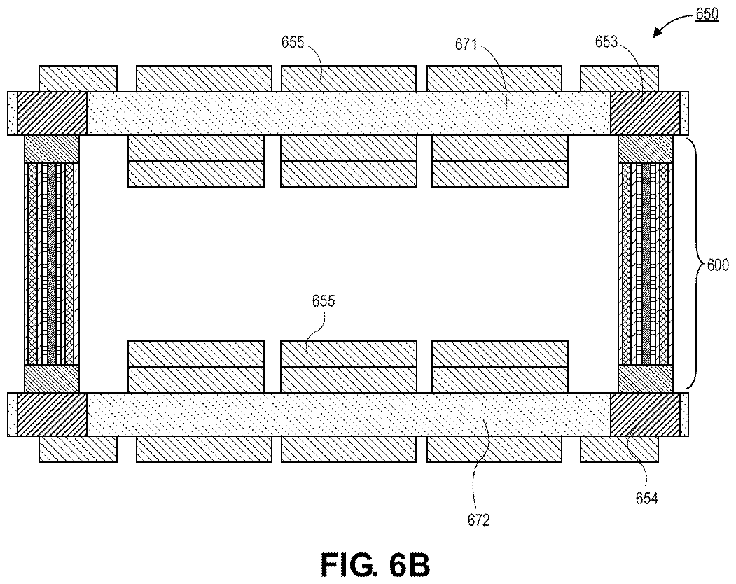

Referring now to FIG. 6A, a cross-sectional illustration of an electronic package 650 is shown, in accordance with an embodiment. In an embodiment, the electronic package 650 may comprise a first die 651 and a second die 652. The first die 651 and the second die 652 may be any type of dies. For example, the first die 651 and the second die 652 may be compute dies (e.g., processors, graphics processors, ASICs, systems on a chip (SoC), or the like). One of the first die 651 and the second die 652 may also be a memory die. The first die 651 is provided over the second die 652 to form a vertical stack.

In an embodiment, the first die 651 is communicatively coupled to the second die 652 by one or more TSWs 600. An air gap may be provided between the first die 651 and the second die 652. The TSWs 600 may be similar to any of the TSWs described in greater detail above. For example, the TSWs 600 may include a substrate 601, TSVs 630, a fill layer 624 and a waveguide structure 620. Cladding (not shown) may also be provided around the waveguide structure 620. In an embodiment, a first PIC 641 and a second PIC 642 may be provided at opposite ends of the TSWs 600. The PICs 641 and 642 may be coupled to electrical integrated circuits (EICs) 653 and 654 that are embedded in the first die 651 and the second die 652, respectively. As such, optical signaling can be used to communicate between two dies that operate in the electrical regime.

Referring now to FIG. 6B, a cross-sectional illustration of an electronic package 650 is shown, in accordance with an additional embodiment. Instead of a having a first die and a second die, the electronic package 650 may include a first interposer 671 and a second interposer 672. The interposers 671 and 672 may comprise EICs 653 and 654. Additionally, one or more components 655 may be coupled to the interposers 671 and 672. The components 655 may include any type of die, cache, phy, or the like. While shown as being attached to the interposers 671 and 672, the components 655 may also be embedded within the interposers 671 and 672.

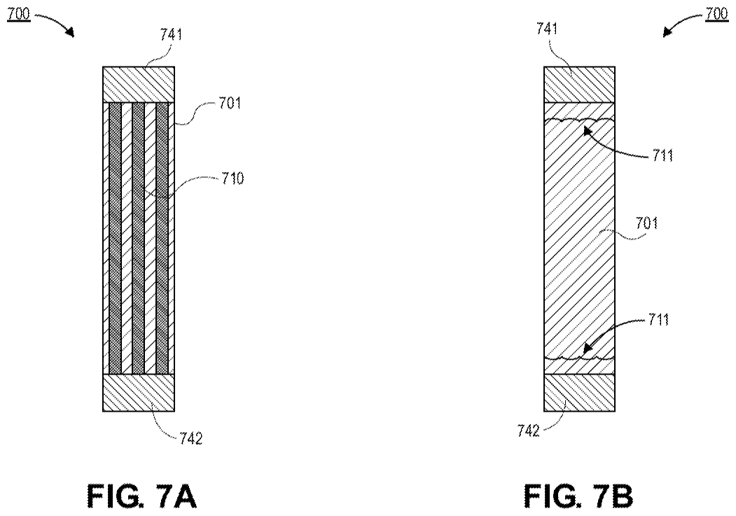

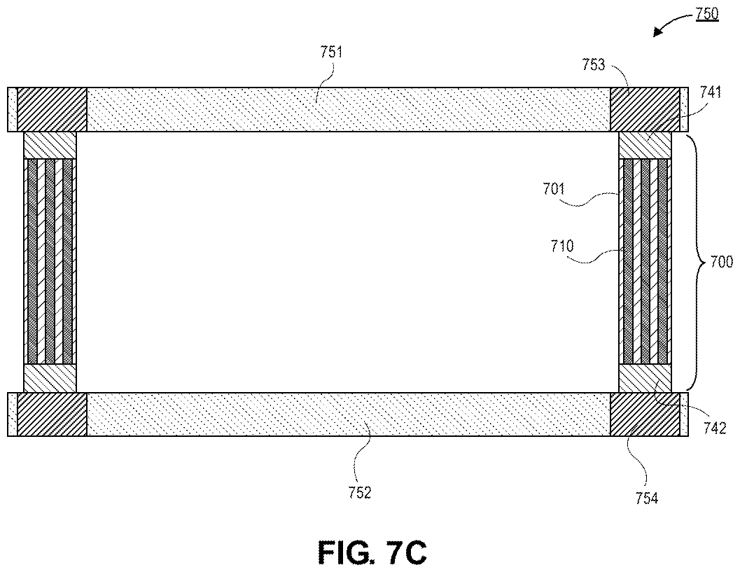

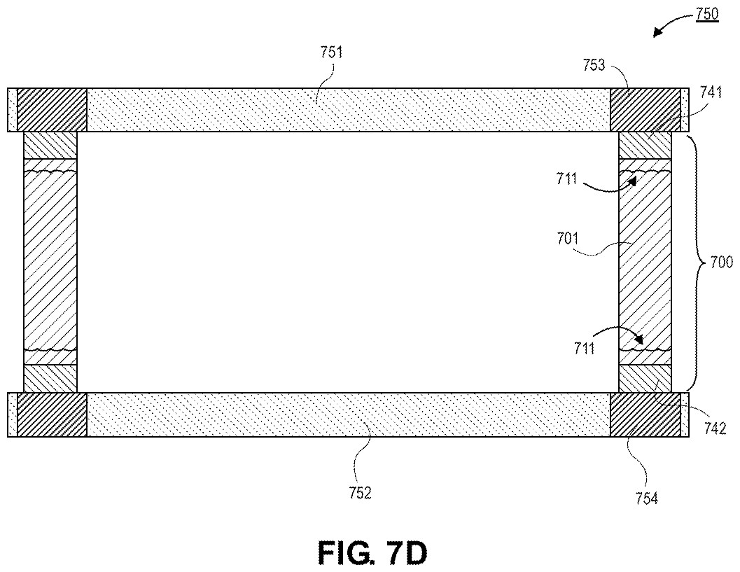

Referring now to FIG. 7A, a cross-sectional illustration of an optical interconnect 700 is shown, in accordance with an additional embodiment. Instead of having a silicon substrate, the optical interconnects 700 may have a glass or dielectric substrate 701. In an embodiment, optical waveguides 710 may be provided through the substrate 701. In an embodiment, the optical waveguides 710 may be glass. When the optical waveguides 710 and the substrate 701 are both glass, the index of refraction of the optical waveguides 710 may be different than the index of refraction of the substrate 701. In an embodiment, PICs 741 and 742 may be provided at opposite ends of the optical interconnect 700.

Referring now to FIG. 7B, a cross-sectional illustration of an optical interconnect 700 is shown, in accordance with an additional embodiment. Instead of having optical waveguides 710, optical signals are coupled between the ends of the optical interconnect 700 by lenses 711. The lenses 711 may focus optical signals that pass through the substrate 701. PICs 741 and 742 may be provided on the ends of the optical interconnect 700.

Referring now to FIG. 7C, a cross-sectional illustration of an electronic package 750 is shown, in accordance with an embodiment. In an embodiment, the electronic package 750 comprises a first die 751 and a second die 752. The first die 751 and the second die 752 may be in a vertical stack arrangement. In an embodiment, the first die 751 and the second die 752 may comprise EICs 753 and 754, respectively. The EICs 753 and 754 may be coupled together by an optical interconnect 700. In the illustrated embodiment, the optical interconnect 700 is similar to the optical interconnect 700 shown in FIG. 7A. For example, a substrate 701, comprises glass optical waveguides 710. PICs 741 and 742 may interface with the EICs 753 and 754.

Referring now to FIG. 7D, a cross-sectional illustration of an electronic package 750 is shown, in accordance with an additional embodiment. In an embodiment, the electronic package 750 in FIG. 7D is substantially similar to the electronic package 750 in FIG. 7C, with the exception of the optical interconnect 700. The optical interconnect 700 may be similar to the optical interconnect 700 in FIG. 7B. That is, lenses 711 may be used to focus optical signals that pass through the substrate 701.

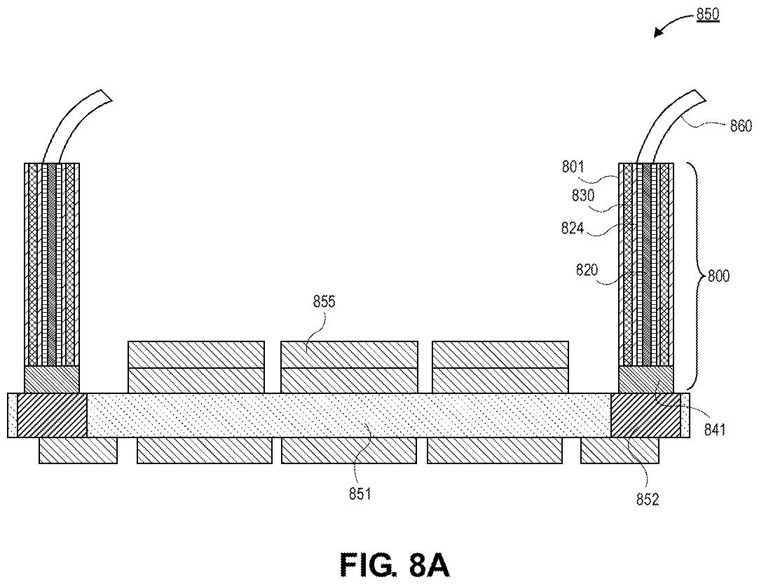

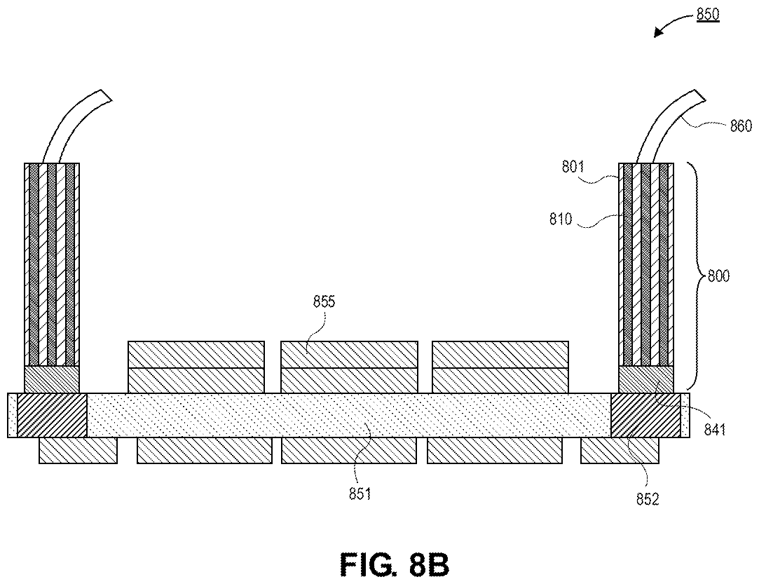

Referring now to FIG. 8A, a cross-sectional illustration of an electronic package 850 is shown, in accordance with an embodiment. In an embodiment, the electronic package 850 may comprise a die/interposer 851. The die/interposer 851 may include EICs 852 and one or more components 855. The components 855 may include any type of die, cache, phy, or the like. In an embodiment, a TSW 800 is provided over the EIC 852. The TSW 800 may comprise a PIC 841 at one end and an optical waveguide 860 at the opposite end. In an embodiment, the TSW 800 may be substantially similar to any of the TSWs described herein. For example, the TSW 800 may comprise a substrate 801, TGVs 830, fill layer 824, and a waveguide structure 820. Cladding (not shown) may also be provided around the waveguide structure 820. In an embodiment, the optical waveguide 860 is coupled to the TSW 800 by butt coupling or evanescent coupling.

Referring now to FIG. 8B, a cross-section of an electronic package 850 is shown, in accordance with an additional embodiment. In an embodiment, the electronic package 850 may be substantially similar to the electronic package 850 with the exception of the TSW 800. Instead of a TSW 800, the electronic package 850 in FIG. 8B includes an optical interconnect 800. The optical interconnect 800 may be similar to any of the optical interconnects described in greater detail herein. For example, the optical interconnect 800 may comprise a substrate 801 with glass optical waveguides 810. In other embodiments, lens structures may replace the glass optical waveguides 810. In an embodiment, the optical waveguide 860 is coupled to the optical interconnect 800 by butt coupling or evanescent coupling.

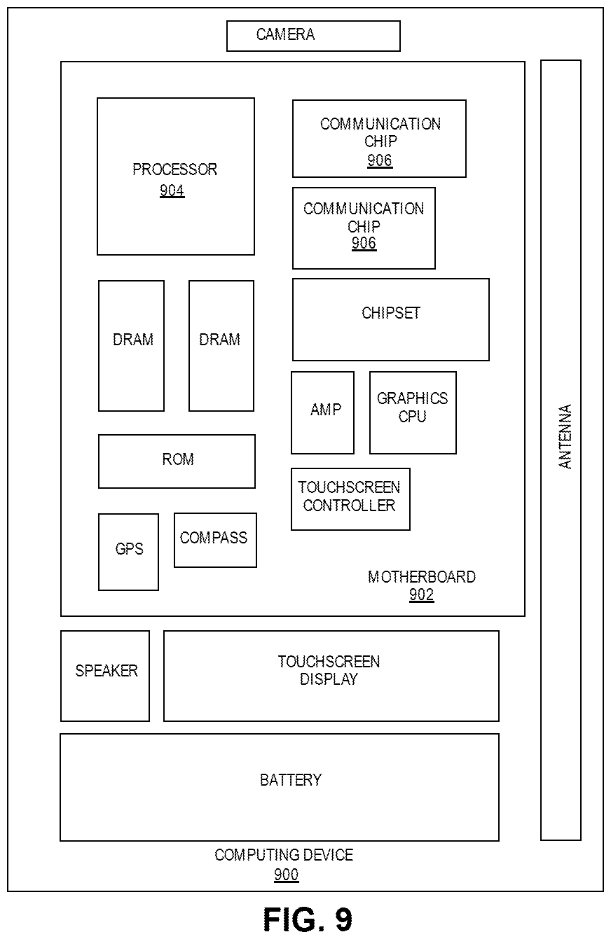

FIG. 9 illustrates a computing device 900 in accordance with one implementation of an embodiment of the present disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. The integrated circuit die of the processor 904 may include one or more structures, such as a TSW that optically couple the processor 904 to an additional component, built in accordance with implementations of embodiments of the present disclosure. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. The integrated circuit die of the communication chip 906 may include one or more structures, such as a TSW that optically couple the communication chip 906 to an additional component, built in accordance with implementations of embodiments of the present disclosure.

In further implementations, another component housed within the computing device 900 may contain an integrated circuit die that includes one or structures, such as a TSW that optically couple the integrated circuit die to an additional component, built in accordance with implementations of embodiments of the present disclosure.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

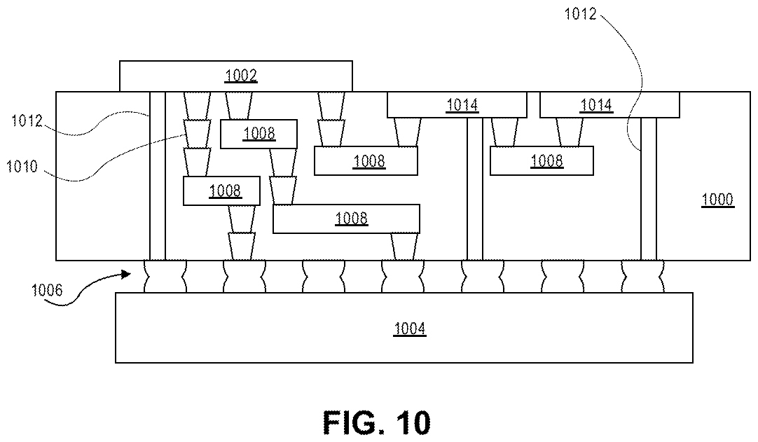

FIG. 10 illustrates an interposer 1000 that includes one or more embodiments of the present disclosure. The interposer 1000 is an intervening substrate used to bridge a first substrate 1002 to a second substrate 1004. The first substrate 1002 may be, for instance, an integrated circuit die. The second substrate 1004 may be, for instance, a memory module, a computer motherboard, or another integrated circuit die. Generally, the purpose of an interposer 1000 is to spread a connection to a wider pitch or to reroute a connection to a different connection. For example, an interposer 1000 may couple an integrated circuit die to a ball grid array (BGA) 1006 that can subsequently be coupled to the second substrate 1004. In some embodiments, the first and second substrates 1002/1004 are attached to opposing sides of the interposer 1000. In other embodiments, the first and second substrates 1002/1004 are attached to the same side of the interposer 1000. And in further embodiments, three or more substrates are interconnected by way of the interposer 1000.

The interposer 1000 may be formed of an epoxy resin, a fiberglass-reinforced epoxy resin, a ceramic material, or a polymer material such as polyimide. In further implementations, the interposer 1000 may be formed of alternate rigid or flexible materials that may include the same materials described above for use in a semiconductor substrate, such as silicon, germanium, and other group III-V and group IV materials.

The interposer 1000 may include metal interconnects 1008 and vias 1010, including but not limited to through-silicon vias (TSVs) 1012. The interposer 1000 may further include embedded devices 1014, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1000. In accordance with embodiments of the disclosure, apparatuses or processes disclosed herein may be used in the fabrication of interposer 1000 or in the fabrication of components included in the interposer 1000.

Thus, embodiments of the present disclosure include integrated circuit structures having a TSW that optically couples the integrated circuit structure to an additional component and methods of forming such TSWs.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a through silicon waveguide, comprising: a substrate, wherein the substrate comprises silicon; and a waveguide through the substrate, wherein the waveguide comprises: a waveguide structure; and a cladding around the waveguide structure.

Example 2: the through silicon waveguide of Example 1, wherein the waveguide structure comprises silicon.

Example 3: the through silicon waveguide of Example 2, wherein the cladding comprises oxygen.

Example 4: the through silicon waveguide of Examples 1-3, wherein the cladding comprises a liner and a fill material.

Example 5: the through silicon waveguide of Examples 1-4, wherein the substrate comprises a plurality of silicon layers bonded together.

Example 6: the through silicon waveguide of Example 5, wherein the plurality of silicon layers have a thickness between approximately 10 μm and approximately 50 μm.

Example 7: the through silicon waveguide of Examples 1-6, wherein the waveguide structure is rectangular.

Example 8: the through silicon waveguide of Examples 1-6, wherein the waveguide structure is cross-shaped.

Example 9: the through silicon waveguide of Examples 1-6, wherein the waveguide structure is T-shaped.

Example 10: the through silicon waveguide of Examples 1-9, further comprising: metal vias adjacent to the waveguide structure.

Example 11: the through silicon waveguide of Examples 1-10, wherein the waveguide structure comprises silicon and nitrogen.

Example 12: the through silicon waveguide of Example 11, wherein the waveguide structure is a shell.

Example 13: the through silicon waveguide of Examples 1-12, wherein a height of the waveguide structure is approximately 100 μm or greater.

Example 14: an electronic package, comprising: a first die, wherein the first die has a first electrical integrated circuit (EIC); a second die over the first die, wherein the second die has a second EIC; a vertical waveguide between the first die and the second die; a first photonics integrated circuit (PIC) on a first end of the vertical waveguide and coupled to the first EIC; and a second PIC on a second end of the vertical waveguide and coupled to the second EIC.

Example 15: the electronic package of Example 14, wherein the vertical waveguide is a through silicon waveguide.

Example 16: the electronic package of Example 14 or Example 15, wherein the vertical waveguide is a glass waveguide.

Example 17: the electronic package of Examples 14-16, wherein the vertical waveguide comprises first lenses at the first end of the vertical waveguide and second lenses at the second end of the vertical waveguide.

Example 18: the electronic package of Examples 14-17, wherein the first die and the second die are interposers.

Example 19: the electronic package of Example 18, further comprising: a plurality of components coupled to the interposers.

Example 20: the electronic package of Examples 14-19, wherein an air gap is provided between the first die and the second die.

Example 21: an electronic package, comprising: a die; an electrical integrated circuit (EIC) integrated with the die; a vertical waveguide extending up from the EIC; a photonics integrated circuit (PIC) between the vertical waveguide and the EIC; and an optical fiber coupled to the vertical waveguide.

Example 22: the electronic package of Example 21, wherein the optical fiber is butt coupled or evanescently coupled to the vertical waveguide.

Example 23: the electronic package of Example 21 or Example 22, wherein the vertical waveguide is a glass waveguide or a through silicon waveguide.

Example 24: an electronic system, comprising: a board; and an electronic package coupled to the board, wherein the electronic package comprises: a die; and a waveguide coupled to the die, wherein the waveguide extends up vertically from the die.

Example 25: the electronic system of Example 24, wherein the waveguide is a through silicon waveguide or a glass waveguide.

What is claimed is:

1. A through silicon waveguide, comprising:
a substrate, wherein the substrate comprises silicon; and
a waveguide through the substrate, wherein the waveguide comprises:
a waveguide structure; and
a cladding around the waveguide structure.

2. The through silicon waveguide of claim 1, wherein the waveguide structure comprises silicon.

3. The through silicon waveguide of claim 2, wherein the cladding comprises oxygen.

4. The through silicon waveguide of claim 1, wherein the cladding comprises a liner and a fill material.

5. The through silicon waveguide of claim 1, wherein the substrate comprises a plurality of silicon layers bonded together.

6. The through silicon waveguide of claim 5, wherein the plurality of silicon layers have a thickness between approximately 10 μm and approximately 50 μm.

7. The through silicon waveguide of claim 1, wherein the waveguide structure is rectangular.

8. The through silicon waveguide of claim 1, wherein the waveguide structure is cross-shaped.

9. The through silicon waveguide of claim 1, wherein the waveguide structure is T-shaped.

10. The through silicon waveguide of claim 1, further comprising:
metal vias adjacent to the waveguide structure.

11. The through silicon waveguide of claim 1, wherein the waveguide structure comprises silicon and nitrogen.

12. The through silicon waveguide of claim 11, wherein the waveguide structure is a shell.

13. The through silicon waveguide of claim 1, wherein a height of the waveguide structure is approximately 100 μm or greater.

14. An electronic package, comprising:
a first die, wherein the first die has a first electrical integrated circuit (EIC);
a second die over the first die, wherein the second die has a second EIC;
a vertical waveguide between the first die and the second die;
a first photonics integrated circuit (PIC) on a first end of the vertical waveguide and coupled to the first EIC; and
a second PIC on a second end of the vertical waveguide and coupled to the second EIC.

15. The electronic package of claim 14, wherein the vertical waveguide is a through silicon waveguide.

16. The electronic package of claim 14, wherein the vertical waveguide is a glass waveguide.

17. The electronic package of claim 14, wherein the vertical waveguide comprises first lenses at the first end of the vertical waveguide and second lenses at the second end of the vertical waveguide.

18. The electronic package of claim 14, wherein the first die and the second die are interposers.

19. The electronic package of claim 18, further comprising:
a plurality of components coupled to the interposers.

20. The electronic package of claim 14, wherein an air gap is provided between the first die and the second die.

21. An electronic package, comprising:
a die;
an electrical integrated circuit (EIC) integrated with the die;
a vertical waveguide extending up from the EIC;
a photonics integrated circuit (PIC) between the vertical waveguide and the EIC; and
an optical fiber coupled to the vertical waveguide.

22. The electronic package of claim 21, wherein the optical fiber is butt coupled or evanescently coupled to the vertical waveguide.

23. The electronic package of claim 21, wherein the vertical waveguide is a glass waveguide or a through silicon waveguide.

24. An electronic system, comprising:
a board; and
an electronic package coupled to the board, wherein the electronic package comprises:
a die; and
a waveguide coupled to the die, wherein the waveguide extends up vertically from the die.

25. The electronic system of claim 24, wherein the waveguide is a through silicon waveguide or a glass waveguide.
